(19) United States
(12) Patent Application Publication
(10) Pub. No.: US 2024/0420777 A1
(43) Pub. Date: Dec. 19, 2024

(54) MEMORY DEVICE AND METHOD OF OPERATING MEMORY DEVICE

(71) Applicant: SK hynix Inc., Icheon-si Gyeonggi-do (KR)

(72) Inventor: Byoung Young KIM, Icheon-si Gyeonggi-do (KR)

(73) Assignee: SK hynix Inc., Icheon-si Gyeonggi-do (KR)

(21) Appl. No.: 18/506,899

(22) Filed: Nov. 10, 2023

(30) Foreign Application Priority Data
Jun. 15, 2023 (KR) 10-2023-0076771

(51) Int. Cl. G11C 16/26; G11C 16/04; G11C 16/08

(52) U.S. Cl. CPC G11C 16/26; G11C 16/0433; G11C 16/08

(57) ABSTRACT

According to an embodiment of the present disclosure, a memory device includes a memory cell array including a plurality of memory cells respectively connected to a plurality of word lines, a peripheral circuit including a voltage generation circuit and page buffers connected to the memory cells and latching data sensed from the memory cells, and a control logic configured to sense data stored in the memory cells in response to a cache read command received from an external device and configured to control the peripheral circuit to output data latched in the page buffers to the external device, and the control logic controls the peripheral circuit to generate an operation voltage to be applied to the word lines based on a comparison result of a first address corresponding to a first cache read command received from the external device and a second address corresponding to a second cache read command.

### CROSS-REFERENCE TO RELATED APPLICATION

The present application claims priority under 35 U.S.C. § 119 (a) to Korean patent application number 10-2023-0076771 filed on Jun. 15, 2023, in the Korean Intellectual Property Office, the entire disclosure of which is incorporated by reference herein.

### BACKGROUND

### 1. Technical Field

The present disclosure relates to a memory device and a method of operating the memory device.

### 2. Related Art

Demand for a NAND-type flash memory device having a high integration degree and a storage device for controlling the flash memory has been increasing as a mobile system and various applications are being developed. A flash memory device has an ability capable of store large amounts of data information but has a disadvantage in that data reading and writing time is somewhat longer than that of a RAM. Performance of a system including such a flash memory device is limited by a read operation time of the flash memory device. The limitation of the system performance by the flash memory device may be solved by supporting a cache read operation.

### SUMMARY

According to an embodiment of the present disclosure, a memory device may include a memory cell array including a plurality of memory cells respectively connected to a plurality of word lines, a peripheral circuit including a voltage generation circuit generating a voltage to be applied to the memory cell array, and page buffers connected to the memory cells through bit lines and latching data sensed from the memory cells, and a control logic configured to sense data stored in the memory cells in response to a cache read command received from an external device and configured to control the peripheral circuit to output data latched in the page buffers to the external device, and the control logic may control the peripheral circuit to generate an operation voltage to be applied to the word lines based on a comparison result of a first address corresponding to a first cache read command received from the external device and a second address corresponding to a second cache read command.

According to an embodiment of the present disclosure, a method of operating a memory device may include applying a first read voltage to a first word line corresponding to a first address, among a plurality of memory cells connected to a plurality of word lines, in response to a first cache read command, sensing first read data stored at a position corresponding to the first address through bit lines to store the first read data in sensing latches connected to the memory cells through the bit lines, receiving a second cache read command and a second address, moving the first read data stored in the sensing latches to caching latches connected to the sensing latches through the bit lines, applying an operation voltage determined based on a comparison result of the first address and the second address to the first word line and a second word line corresponding to the second address, and sensing second read data stored at a position corresponding to the second address to store the second read data in the sensing latches, and outputting the first read data stored in the caching latch.

### BRIEF DESCRIPTION OF THE DRAWINGS

FIG. 1 is a block diagram illustrating a memory device according to an embodiment of the present disclosure.

FIG. 2 is a diagram illustrating a voltage control circuit of the memory device of FIG. 1.

FIG. 3 is a diagram illustrating an address comparing circuit of FIG. 2.

FIG. 4 is a diagram illustrating a voltage control signal generator of FIG. 2.

FIG. 5 is a diagram illustrating a page buffer group of FIG. 1.

FIG. 6 is a diagram illustrating transferal of data during a normal read operation.

FIG. 7 is a diagram illustrating transferal of data during a cache read operation.

FIG. 8 is a timing diagram illustrating the cache read operation.

FIG. 9 is a diagram illustrating a voltage applied to each of lines during the cache read operation.

FIG. 10 is a timing diagram illustrating a cache read operation of a memory device according to an embodiment of the present disclosure.

FIG. 11 is a diagram illustrating an example of a voltage applied to each of lines during a cache read operation of a memory device according to an embodiment of the present disclosure.

FIG. 12 is a diagram illustrating another example of a voltage applied to each of lines during a cache read operation of a memory device according to an embodiment of the present disclosure.

FIG. 13 is a timing diagram illustrating a cache read operation of a memory device according to another embodiment of the present disclosure.

FIG. 14 is a diagram illustrating a voltage applied to each of lines during a cache read operation of a memory device according to another embodiment of the present disclosure.

FIG. 15 is a block diagram illustrating a storage device including a memory device according to an embodiment of the present disclosure.

FIG. 16 is a diagram illustrating another embodiment of a memory controller of FIG. 15.

FIG. 17 is a flowchart illustrating a method of operating a memory device according to an embodiment of the present disclosure.

FIG. 18 is a flowchart illustrating a voltage application process in a method of operating a memory device according to an embodiment of the present disclosure.

FIG. 19 is a flowchart illustrating a voltage application process in a method of operating a memory device according to another embodiment of the present disclosure.

### DETAILED DESCRIPTION

Specific structural or functional descriptions of embodiments according to the concept of the present disclosure disclosed in the present specification or application are illustrated only to describe the embodiments according to the concept of the present disclosure. The embodiments according to the concept of the present disclosure may be carried out in various forms and are not limited to the embodiments described in the present specification or application.

Embodiments of the present disclosure provide a memory device and a method of operating the memory device capable of improving read operation performance.

According to the present technology, a memory device and a method of operating the memory device capable of improving read operation performance are provided.

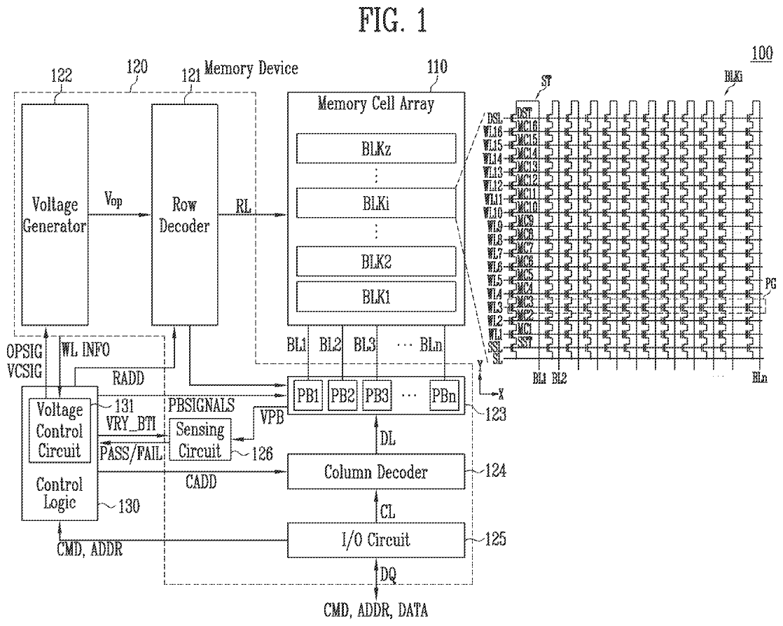

FIG. 1 is a block diagram illustrating a memory device according to an embodiment of the present disclosure.

Referring to FIG. 1, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz may be connected to a row decoder 121 through row lines RL. Here, the row lines RL may include at least one source select line, a plurality of word lines, and at least one drain select line. The plurality of memory blocks BLK1 to BLKz may be connected to a page buffer group 123 through bit lines BL1 to BLn. Each of the plurality of memory blocks BLK1 to BLKz may include a plurality of memory cells. As an embodiment, the plurality of memory cells may be nonvolatile memory cells. Memory cells connected to the same word line may be defined as one page. Therefore, one memory block may include a plurality of pages.

In any one memory block BLKi, among the plurality of memory blocks, a plurality of word lines arranged in parallel with each other may be connected between a first select line and a second select line. Here, the first select line may be a source select line SSL, and the second select line may be a drain select line DSL. More specifically, the memory block BLKi may include a plurality of strings ST connected between bit lines BL1 to BLn and a source line SL. The bit lines BL1 to BLn may be connected to the strings ST, respectively, and the source line SL may be commonly connected to the strings ST. Since the strings ST may be configured to be identical to each other, a string ST connected to the first bit line BL1 is specifically described as an example.

The string ST may include a source select transistor SST, a plurality of memory cells MC1 to MC16, and a drain select transistor DST connected in series between the source line SL and the first bit line BL1. One string ST may include at least one or more of the source select transistor SST and the drain select transistor DST and may include the memory cells MC1 to MC16. However, one string ST may include more memory cells than shown in the figure.

A source of the source select transistor SST may be connected to the source line SL, and a drain of the drain select transistor DST may be connected to the first bit line BL1. The memory cells MC1 to MC16 may be connected in series between the source select transistor SST and the drain select transistor DST. Gates of the source select transistors SST included in the different strings ST may be connected to the source select line SSL, gates of the drain select transistors DST may be connected to the drain select line DSL, and gates of the memory cells MC1 to MC16 may be connected to a plurality of word lines WL1 to WL16. A group of the memory cells connected to the same word line, among the memory cells included in different strings ST, may be referred to as a physical page PPG. Therefore, the memory block BLKi may include the physical pages PPG of the number of the word lines WL1 to WL16.

Each of the memory cells included in the memory cell array 110 may be configured as a single level cell (SLC) that stores one data bit, a multi-level cell (MLC) that stores two data bits, a triple level cell (TLC) that stores three data bits, or a quad level cell (QLC) that stores four data bits.

The SLC may store one bit of data. One physical page PPG of the SLC may store one logical page data. One logical page LPG data may include data bits corresponding to the number of cells included in one physical page PPG.

The MLC, the TLC, and the QLC may store two or more bits of data. In this case, one physical page PPG may store two or more logical page data.

The peripheral circuit 120 may be configured to perform a program operation, a read operation, or an erase operation on the selected area of the memory cell array 110 under the control of the control logic 130. That is, the peripheral circuit 120 may drive the memory cell array 110 under the control of the control logic 130. For example, the peripheral circuit 120 may apply various operation voltages to the row lines RL and the bit lines BL1 to BLn or may discharge the applied voltages under the control of the control logic 130. Here, an operation that discharges the applied voltages may also be expressed as applying a discharge voltage.

Specifically, the peripheral circuit 120 may include a row decoder 121, a voltage generator 122, a page buffer group 123, a column decoder 124, an input/output circuit 125, and a sensing circuit 126.

The row decoder 121 may be connected to the memory cell array 110 through the row lines RL. The row lines RL may include at least one source select line, a plurality of word lines, and at least one drain select line. In an embodiment, the word lines may include normal word lines and dummy word lines. In addition, the row lines RL may further include a pipe select line.

The row decoder 121 may be configured to operate in response to the control of the control logic 130. The row decoder 121 may receive a row address RADD from the control logic 130. Specifically, the row decoder 121 may be configured to decode the row address RADD. The row decoder 121 may select at least one of the memory blocks BLK1 to BLKz according to a decoded row address RADD. In addition, the row decoder 121 may select at least one word line of the memory block, which is selected to apply the voltages generated by the voltage generator 122 to at least one word line according to the decoded address.

For example, during the program operation, the row decoder 121 may apply the program voltage to a selected word line and may apply a program pass voltage that has a lower level than the program voltage to an unselected word line. During a program verify operation, the row decoder 121 may apply a verify voltage to the selected word line and a verify pass voltage that has a higher level than the verify voltage to the unselected word line. During the read operation, the row decoder 121 may apply a read voltage to the selected word line and may apply a read pass voltage that has a higher level than the read voltage to the unselected word line.

In an embodiment, the erase operation of the memory cell array 110 may be performed in a memory block unit. During the erase operation, the row decoder 121 may select one memory block according to the decoded address, and the row decoder 121 may apply a ground voltage to word lines connected to the selected memory block.

The voltage generator 122 may operate in response to the control of the control logic 130. The voltage generator 122 may be configured to generate a plurality of voltages by using an external power voltage supplied to the memory device 100. For example, the voltage generator 122 may generate the program voltage, the verify voltage, the pass voltage, the read voltage, the erase voltage, and the like in response to the control of the control logic 130. That is, the voltage generator 122 may generate various operation voltages Vₒₚ used for the program, read, and erase operations in response to an operation signal OPSIG and a voltage control signal VCSIG.

As an embodiment, the voltage generator 122 may generate an internal power voltage by regulating the external power voltage. The internal power voltage generated by the voltage generator 122 may be used as an operation voltage of the memory cell array 110.

As an embodiment, the voltage generator 122 may generate a plurality of voltages by using the external power voltage or the internal power voltage. For example, in response to the control of the control logic 130, the voltage generator 122 may include a plurality of pumping capacitors that receive the internal power voltage and may selectively activate the plurality of pumping capacitors to generate the plurality of voltages. In addition, the generated voltages may be supplied to the memory cell array 110 by the row decoder 121.

The page buffer group 123 may include first to n-th page buffers PB1 to PBn. The first to n-th page buffers PB1 to PBn may be connected to the memory cell array 110 through the first to n-th bit lines BL1 to BLn, respectively. In addition, the first to n-th page buffers PB1 to PBn may operate in response to the control of the control logic 130. Specifically, the first to n-th page buffers PB1 to PBn may operate in response to page buffer control signals PBSIGNALS. For example, the first to n-th page buffers PB1 to PBn may temporarily store data received through the first to n-th bit lines BL1 to BLn or may sense a voltage or a current of the bit lines BL1 to BLn during the read or verify operation.

Specifically, during the program operation, when a program pulse is applied to the selected word line, the first to n-th page buffers PB1 to PBn may transfer data DATA received through the input/output circuit 125 to the selected memory cells through the first to n-th bit lines BL1 to BLn. The memory cells of the selected page may be programmed according to the transferred data DATA. Memory cells of a page selected according to the transferred data DATA may be programmed. A memory cell connected to a bit line to which a program allowable voltage (for example, a ground voltage) is applied may have an increased threshold voltage. A threshold voltage of a memory cell connected to a bit line to which a program inhibition voltage (for example, a power voltage) is applied may be maintained.

During the program verify operation, the first to n-th page buffers PB1 to PBn may read page data from the selected memory cells through the first to n-th bit lines BL1 to BLn.

During the read operation, the first to n-th page buffers PB1 to PBn may read the data DATA from memory cells of a selected page through the first to n-th bit lines BL1 to BLn and may output the read data DATA to the input/output circuit 125 under the control of the column decoder 124.

During the erase operation, the first to n-th page buffers PB1 to PBn may float the first to n-th bit lines BL1 to BLn.

In an embodiment, each of the page buffers PB1 to PBn may include sensing latches and caching latches. The sensing latches may latch the read data sensed through the bit lines BL1 to BLn. The caching latches may cache the data stored in the sensing latch.

In an embodiment, under the control of the control logic 130, the page buffer group 123 may latch the sensed read data to the sensing latches and may output the data stored in the caching latches simultaneously.

In an embodiment, under the control of the control logic 130, the page buffer group 123 may move the read data latched in the sensing latches to the caching latch.

The column decoder 124 may transfer data between the input/output circuit 125 and the page buffer group 123 in response to a column address CADD. For example, the column decoder 124 may exchange data with the first to n-th page buffers PB1 to PBn through data lines DL or may exchange data with the input/output circuit 125 through column lines CL.

The input/output circuit 125 may transfer a command CMD and an address ADDR received from an external memory controller 200 to the control logic 130 or may exchange the data DATA with the memory controller through an input/output line DQ. In addition, the input/output circuit may exchange data with the column decoder 124 through column lines CL.

The sensing circuit 126 may generate a reference current in response to an allowable bit signal VRY_BIT during the read operation or the verify operation and may compare a sensing voltage VPB received from the page buffer group 123 with a reference voltage generated by the reference current to output a pass signal PASS or a fail signal FAIL.

The control logic 130 may output the operation signal OPSIG, the voltage control signal VCSIG, the row address RADD, the page buffer control signals PBSIGNALS, and the allowable bit signal VRY_BIT in response to the command CMD and the address ADDR to control the peripheral circuit 120.

The control logic 130 may control the peripheral circuit 120 to perform a normal read operation and a cache read operation according to the command CMD provided from the outside. In an embodiment, the control logic 130 may include a voltage control circuit 131. The voltage control circuit 131 may control the voltage generator 122 to generate the operation voltages Vₒₚ by outputting the operating signal OPSIG and the voltage control signal VCSIG.

In an embodiment, the voltage control circuit 131 may generate the voltage control signal VCSIG in response to the address ADDR received from the input/output circuit 125, and more specifically, the voltage control circuit 131 may generate the voltage control signal VCSIG related to the cache read operation based on a result of comparing addresses corresponding to successive cache read commands.

In addition, the voltage control circuit 131 may receive word line state information WL INFO from the peripheral circuit 120. The voltage control circuit 131 may generate the voltage control signal VCSIG related to the cache read operation based on the word line state information WL INFO at a time point at which the cache read command is received.

In addition, the control logic 130 may generate the operating signal OPSIG in response to the command CMD, and the voltage generator 122 may generate the operation voltage Vₒₚ based on the received operating signal OPSIG and voltage control signal VCSIG.

In FIG. 1, the voltage control circuit 131 may be included in the control logic 130. However, the embodiment is not limited thereto, and the voltage control circuit 131 may be included in the peripheral circuit 120 or may be a separate configuration distinguished from the control logic 130 and the peripheral circuit 120.

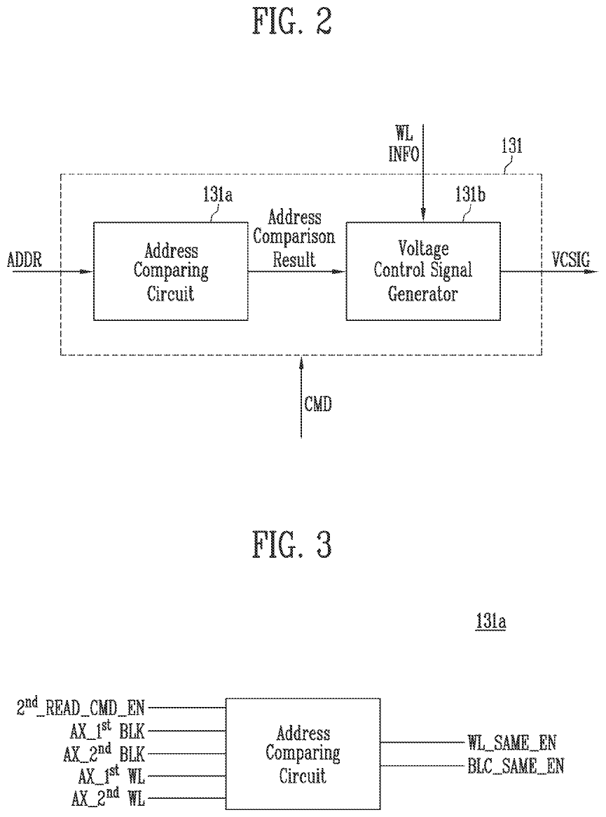

FIG. 2 is a diagram illustrating the voltage control circuit of the memory device of FIG. 1.

Referring to FIGS. 1 and 2, the voltage control circuit 131 may include an address comparing circuit 131a and a voltage control signal generator 131b. The address comparing circuit 131a may receive the address ADDR through the input/output line DQ.

In an embodiment, the address comparing circuit 131a may latch the received address. In an embodiment, the address comparing circuit 131a may compare a latched first address with a newly received second address.

In an embodiment, the address comparing circuit 131a may be enabled according to a cache read command. That is, when the address comparing circuit 131a receives the cache read command, the address comparing circuit 131a may compare the first address with the second address. In an embodiment, the address comparing circuit 131a may latch the received address according to whether the cache read command has been received, and thus, the address comparing circuit 131a may compare the latched address with the newly received address. In another embodiment, the address comparing circuit 131a may compare the latched address with the newly received address according to whether the cache read command has been received, and thus, the address comparing circuit 131a may output an address comparison result.

In an embodiment, the address comparing circuit 131a may compare block addresses of the first address with the second address. In addition, in an embodiment, the address comparing circuit 131a may compare word line addresses of the first address with the second address.

In an embodiment, the address comparing circuit 131a may output a comparison result of addresses. In an embodiment, the address comparing circuit 131a may output at least one of a block address comparison result and a word line address comparison result as the address comparison result.

The voltage control signal generator 131b may receive the address comparison result output from the address comparing circuit 131a. In addition, the voltage control signal generator 131b may receive the word line state information WL INFO from the peripheral circuit 120. The word line state information WL INFO may indicate a voltage applied to each of the word lines connected to the memory cells. In an embodiment, the word line state information WL INFO may include information regarding a voltage applied to one or more word lines from among a word line corresponding to the first address and a word line corresponding to the second address. In addition, in an embodiment, the word line state information WL INFO may further include information regarding a voltage applied to the drain select line. More specifically, the word line state information WL INFO may further include information regarding a voltage applied to a selected drain select line and a voltage applied to an unselected drain select line.

The voltage control signal generator 131b may output the voltage control signal VCSIG based on the address comparison result received from the address comparing circuit 131a and the word line state information WL INFO received from the peripheral circuit 120.

In an embodiment, when the command CMD received by the control logic 130 is the cache read command, the voltage generator 122 may generate a voltage for a cache read operation. Accordingly, the voltage signal generator 131b may generate and output the voltage control signal VCSIG so that the voltage generator 122 generates at least one of the following: one or more read voltages applied to the selected word line and sensing data stored in the memory cells, one or more pass voltages applied to the unselected word line and maintaining the memory cells connected to the unselected word line in a turn-on state, an equalizing voltage for synchronizing voltages of the selected word line and the unselected word line, and a discharge voltage for discharging the selected word line and the unselected word line. FIG. 3 is a diagram illustrating the address comparing circuit of FIG. 2.

Referring to FIGS. 1 to 3, a signal indicating whether a previous address, a current address, and a subsequent read command have been received may be input to the address comparing circuit 131a.

In an embodiment, the memory device 100 may receive a first cache read command and a second cache read command sequentially from an external device and may receive the first address and the second address corresponding to each cache read command.

Accordingly, a first block address AX_1^{st} BLK corresponding to the first address, a second block address AX_2^{nd}BLK corresponding to the first address, a first word line address AX_1^{st} WL corresponding to the first address, a second word line address AX_2^{nd} WL corresponding to the second address, and a second cache read command enable signal 2^{nd}_READ_CMD_EN indicating the reception of the second cache read command may be input to the address comparing circuit 131a.

In an embodiment, the address comparing circuit 131a may compare the first address with the second address according to the second cache read command enable signal 2^{nd}_READ_CMD_EN. That is, when the memory device 100 receives the second cache read command, the address comparison result may be output from the address comparing circuit 131a according to the comparison of the first address with the second address.

The address comparing circuit 131a may compare the first block address AX_1^{st} BLK with the second block address AX_2^{nd} BLK. The address comparing circuit 131a may compare the first word line address AX_1^{st} WL with the second word line address AX_2^{nd} WL.

The address comparing circuit 131a may output a block address comparison result BLC_SAME_EN according to whether the first block address AX_1^{st} BLK and the second block address AX_2^{nd} BLK are the same. In addition, the address comparing circuit 131a may output a word line address comparison result WL_SAME_EN according to whether the first word line address AX_1^{st} WL and the second word line address AX_2^{nd} WL are the same.

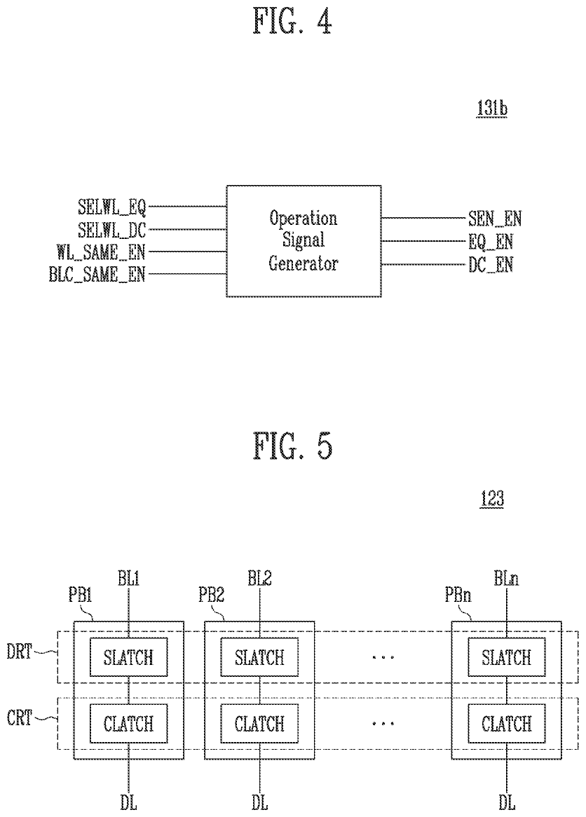

FIG. 4 is a diagram illustrating the voltage control signal generator of FIG. 2.

Referring to FIGS. 1 to 4, a signal indicating the address comparison result and the word line state information may be input to the voltage control signal generator 131b.

In an embodiment, the voltage control signal generator 131b may receive the block address comparison result BLC_SAME_EN and the word line address comparison result WL_SAME_EN from the address comparing circuit 131a.

In addition, the voltage control signal generator 131b may receive the word line state information from the peripheral circuit 120, and more specifically, equalizing voltage application information SELWL_EQ of the selected word line and discharge voltage application information SELWL_DC of the selected word line.

The voltage control signal generator 131b may output the voltage control signal VCSIG based on the received address comparison result and word line state information. In an embodiment, the voltage control signal may include an equalizing enable signal EQ_EN requesting generation of the equalizing voltage for performing an equalization, a discharge enable signal DC_EN requesting generation of the discharge voltage for performing a discharge, and a sensing enable signal SEN_EN requesting generation of the read voltage for performing a sensing operation. However, the voltage control signal VCSIG is not limited thereto, and various types of signals requesting generation of an operation voltage for performing the read operation and a preparation operation and a finishing operation of the read operation may be further included.

FIGS. 2 to 4 illustrate an example of the voltage control circuit 131 of FIG. 1. However, a configuration of the voltage control circuit 131 is not limited to the configuration of FIGS. 2 to 4, and any configuration capable of controlling the generation of the operation voltage based on a comparison result of addresses corresponding to cache read commands and word line state information corresponding to a reception time point of a subsequent cache read command is not limited and may be adopted as the configuration of the voltage control circuit 131.

FIG. 5 is a diagram illustrating the page buffer group of FIG. 1.

Referring to FIGS. 1 and 5, each of the page buffers PB1, PB2, . . . , and PBn included in the page buffer group 123 may include a sensing latch SLATCH and a cache latch CLATCH.

The page buffers PB1, PB2, . . . , and PBn may operate in response to control signals of the control logic 130 during the read operation. Specifically, the control logic 130 may receive the cache read command from a memory controller, and in response to the cache read command, the control logic 130 may generate and transmit the control signals PBSIGNALS controlling the cache read operation of the page buffers PB1, PB2, . . . , and PBn to the page buffers PB1, PB2, . . . , and PBn, and the page buffers PB1, PB2, . . . , and PBn may perform the cache read operation in response to the page buffer control signals.

The sensing latch SLATCH may store data sensed from the bit line. The data sensed from the bit line may be data determined according to a threshold voltage characteristic of memory cells connected to a selected word line, among local word lines. For example, the sensing latch SLATCH of the first page buffer PB1 may be connected to the first bit line BL1 and may latch (or store) data sensed from the first bit line BL1.

The cache latch CLATCH may be electrically connected to the sensing latch SLATCH and may cache (or store) the data stored in the sensing latch SLATCH in response to the page buffer control signals. In addition, the cache latch CLATCH may be connected to the data lines DL and may output cached data to the column decoder 124 through the data lines DL.

The sensing latches SLATCH included in the page buffers PB1, PB2, . . . , and PBn may be referred to as one data register DRT, and the cache latches CLATCH included in the page buffers may be referred to as one cache register CRT. At this time, since the data register DRT and the cache register CRT store or cache data sensed from memory cells connected to one word line, data corresponding to one page may be stored.

The data cached in the cache register CRT may be output to the input/output lines DQ through the column decoder 124 and the input/output circuit 125, and the memory controller 1200 may receive the data cached in the cache register CRT through the input/output lines DQ in response to the cache read command transmitted to the control logic 130.

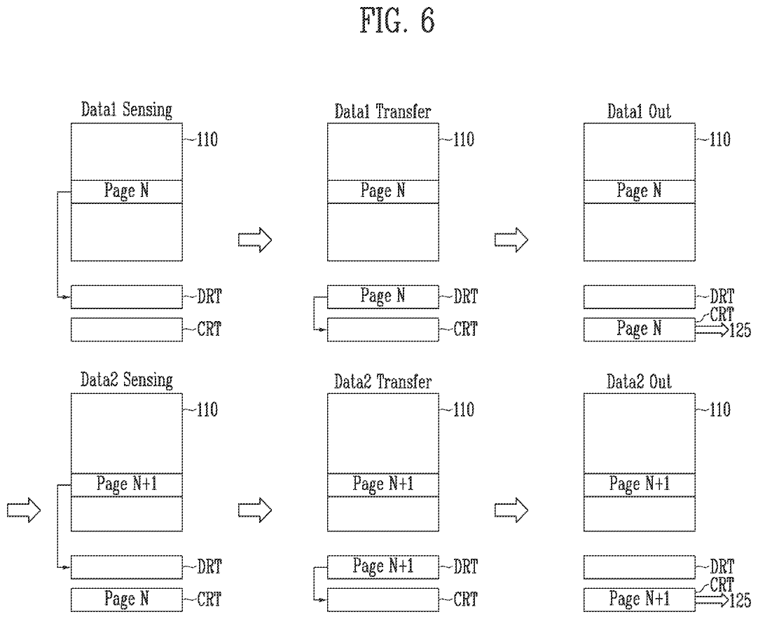

FIG. 6 is a diagram illustrating transferal of data during the normal read operation.

Referring to FIGS. 1, 5, and 6, the memory device 100 may receive a first normal read command and a first address corresponding thereto. Accordingly, a data sensing operation (Data1 Sensing) for a page N in the memory cell array 110 corresponding to the first address may be performed. As a result, data of the page N may be stored in the data register DRT including the sensing latches.

Next, a data transfer operation (Data1 Transfer) of the data of the page N stored in the data register DRT may be performed, and thus, the data of the page N stored in the data register DRT may be transferred to the cache register CRT including the caching latches.

Next, an output operation (Data1 Out) of the data of the page N stored in the cache register CRT may be performed, and thus, the data of the page N stored in the cache register CRT may be output to an external memory controller through the input/output line DQ.

When the output operation (Data1 Out) of the data of the page N is completed, the memory device 100 may receive a second normal read command and a second address corresponding thereto. Accordingly, a data sensing operation (Data2 Sensing) for a page N+1 in the memory cell array 110 corresponding to the second address may be performed. As a result, data of the page N+1 may be stored in the data register DRT.

Next, as a data transfer operation (Data2 Transfer) of the data of the page N+1 stored in the data register DRT is performed, the data of the page N+1 stored in the data register DRT may be transferred to the cache register CRT.

Next, an output operation (Data2 Out) of the data of the page N+1 stored in the cache register CRT may be performed, and thus, the data of the page N+1 stored in the cache register CRT may be output to the external memory controller through the input/output line DQ.

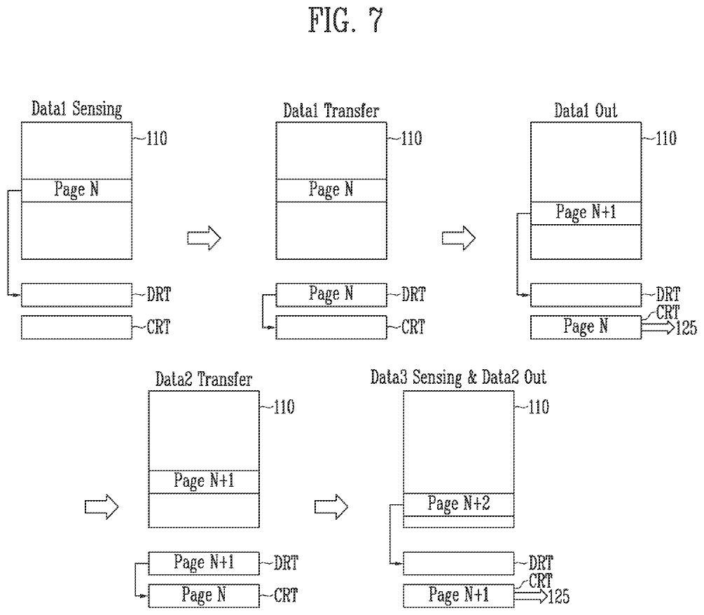

FIG. 7 is a diagram illustrating transferal of data during the cache read operation.

Referring to FIGS. 1, 5, and 7, the memory device 100 may receive a first cache read command and a first address corresponding thereto. Accordingly, a data sensing operation (Data1 Sensing) for a page N in the memory cell array 110 corresponding to the first address may be performed. As a result, data of the page N may be stored in the data register DRT including the sensing latches.

Next, a data transfer operation (Data1 Transfer) of the data of the page N stored in the data register DRT may be performed, and thus, the data of the page N stored in the data register DRT may be transferred to the cache register CRT including the caching latches. In an embodiment, during the data transfer operation, the memory device 100 may receive a second cache read command and a second address corresponding thereto.

Next, an output operation (Data1 Out) of the data of the page N stored in the cache register CRT may be performed, and at the same time, a data sensing operation (Data2 Sensing) for a page N+1 in the memory cell array 110 corresponding to the second address may be performed. Accordingly, the data of the page N stored in the cache register CRT may be output to an external memory controller through the input/output line DQ, and data of the page N+1 may be stored in the data register DRT simultaneously.

Next, a data transfer operation (Data2 Transfer) of the data of the page N+1 stored in the data register DRT may be performed, and thus, the data of the page N stored in the data register DRT may be transferred to the cache register CRT including the caching latches. In an embodiment, during the data transfer operation, the memory device 100 may receive a third cache read command and a third address corresponding thereto.

Next, an output operation (Data2 Out) of the data of the page N+1 stored in the cache register CRT may be performed, and at the same time, a data sensing operation (Data2 Sensing) for a page N+2 in the memory cell array 110 corresponding to the third address may be performed. Accordingly, the data of the page N+1 stored in the cache register CRT may be output to the external memory controller through the input/output line DQ, and data of the page N+2 may be stored in the data register DRT simultaneously.

That is, in the case of the cache read operation, a time for reading data may be shortened compared to the normal read operation.

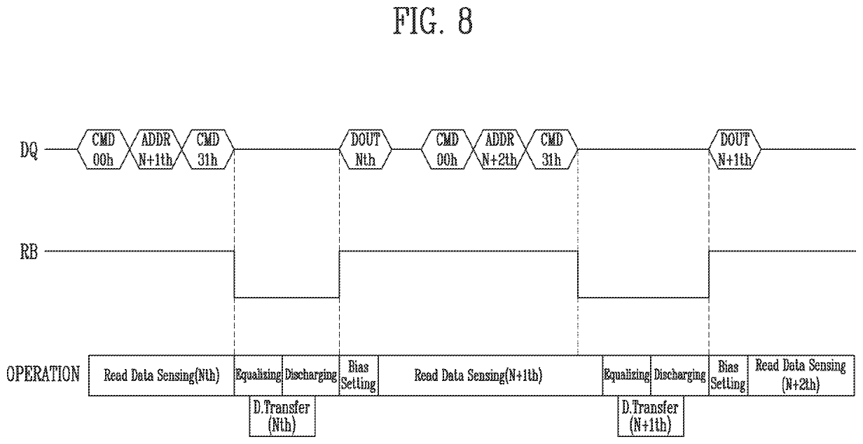

FIG. 8 is a timing diagram illustrating the cache read operation.

Referring to FIGS. 1, 7, and 8, FIG. 8 shows a command and an addresses input through the input/output lines DQ of FIG. 1 and data output through the input/output lines DQ. In addition, FIG. 8 shows a ready busy signal output through a ready busy line RB of the memory device 100 of FIG. 1 and an operation performed in the memory device in response to the ready busy signal.

In an embodiment, during the cache read operation, the command and the address may be input from a memory controller that is external to the memory device 100 through the input/output lines DQ. During the cache read operation, a 00h command CMD 00h, an (N+1)-th address ADDR (N+1)th, and a 31h command CMD 31h are sequentially input through the input/output lines DQ.

In an embodiment, before the 31h command CMD 31h is input, data corresponding to an N-th address Nth ADDR may be sensed (Read Data Sensing (Nth)). The N-th address ADDR Nth may be an address received before the (N+1)-th address ADDR (N+1) th is received.

When all data corresponding to the N-th address ADDR Nth are stored in the data register DRT, the data stored in the data register DRT may be transferred to the cache register CRT (D.Transfer(Nth)). At this time, an equalizing operation

Equalizing and a discharge operation Discharge on the selected word line may be simultaneously performed. Here, the selected word line may be a word line corresponding to the N-th address ADDR Nth.

The equalizing operation Equalizing may be an operation that synchronizes voltages of the selected word line and the unselected word lines before discharging each of the selected word line to which the read voltage is applied and the unselected word lines to which the pass voltage is applied. The equalizing voltage may be applied to both of the selected word line and the unselected word lines for the equalizing operation Equalizing.

The discharge operation Discharge may be an operation that discharges the selected word line to which the read voltage is applied and the unselected word lines to which the pass voltage is applied. The discharge voltage may be applied to both of the selected word line and the unselected word line for the discharge operation Discharge.

The equalizing operation Equalizing may be an operation selectively performed prior to the discharge operation Discharge. However, when the equalizing operation Equalizing is performed prior to the discharge operation Discharge, voltage levels of the selected word line and the unselected word lines may be the same. Accordingly, when the discharge operation Discharge is performed on the selected word line and the unselected word lines on which the equalizing operation Equalizing has been performed, the selected word line and the unselected word lines may be discharged to the same level at the same discharge time.

Thereafter, the memory device 100 may output the data (DOUT Nth) corresponding to the N-th address ADDR Nth stored in the cache register CRT through the input/output lines DQ and may sense the data corresponding to the (N+1)-th address ADDR (N+1) th (Read Data Sensing ((N+1) th)) simultaneously. In the cache read operation, since the data is stored in the data register DRT and the data stored in the cache register CRT is output simultaneously, the data corresponding to the (N+1)-th address ADDR (N+1) th may be stored in the data register DRT and the data corresponding to the N-th address ADDR Nth stored in the cache register CRT may be output to the external memory controller simultaneously.

At this time, a voltage setting operation Bias Setting may be performed before the data sensing operation Read Data Sensing ((N+1) th) for the selected word line. Here, the selected word line may be a word line corresponding to the (N+1)-th address ADDR (N+1) th.

The voltage setting operation Bias Setting may be an operation that changes a voltage applied to the selected word line to the read voltage that senses the data corresponding to the (N+1)-th address ADDR (N+1) th. In an embodiment, the voltage applied to the selected word line during the voltage setting operation Bias Setting may be changed from a discharged voltage to the read voltage. In another embodiment, the voltage applied to the selected word line during the voltage setting operation Bias Setting may be precharged from the discharged voltage to a precharge voltage and then may be changed to the read voltage.

In an embodiment, when the data corresponding to the N-th address ADDR Nth is output, the memory device 100 may receive a subsequent cache read command and address from the memory controller through the input/output lines DQ. For example, after outputting the data corresponding to the N-th address ADDR Nth, the memory device 100 may receive the 00h command CMD 00h, an (N+2)-th address ADDR (N+2) th, and a 31h command CMD 31h through the input/output lines DQ.

After receiving the 31h command CMD 31h, when all data corresponding to the (N+1)-th address ADDR (N+1)th is stored in the data register DRT, the data stored in the data register DRT may be transferred to the cache register CRT (D.Transfer((N+1)th)). At this time, the equalizing operation Equalizing and the discharge operation Discharge on the selected word line may be simultaneously performed. Here, the selected word line may be a word line corresponding to the (N+1)-th address ADDR (N+1)th.

Thereafter, the memory device 100 may output the data (DOUT (N+1)th) corresponding to the (N+1)-th address ADDR (N+1) th stored in the cache register CRT through the input/output lines DQ and may sense data corresponding to the (N+2)-th address ADDR (N+2)th (Read Data Sensing ((N+2)th)) simultaneously. In the cache read operation, since the data is stored in the data register DRT and the data stored in the cache register CRT is output simultaneously, the data corresponding to the (N+2)-th address ADDR (N+2) th may be stored in the data register DRT and the data corresponding to the (N+1)-th address ADDR (N+1)th stored in the cache register CRT may be output to the external memory controller simultaneously.

At this time, the voltage setting operation Bias Setting may be performed before the data sensing operation (Read Data Sensing ((N+2)th)) for the selected word line. Here, the selected word line may be a word line corresponding to the (N+2)-th address ADDR (N+2)th.

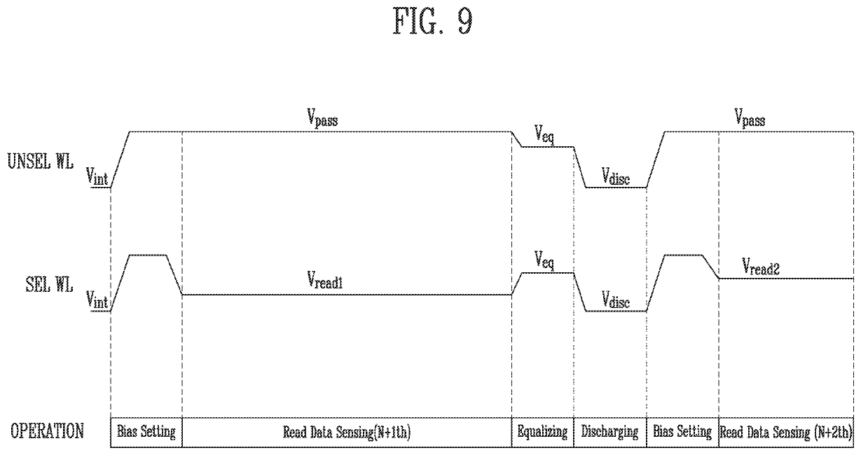

FIG. 9 is a diagram illustrating a voltage applied to each line during the cache read operation.

Referring to FIGS. 8 and 9, according to the voltage setting operation Bias Setting performed before an operation that senses the data corresponding to the (N+1)-th address ADDR (N+1)th (Read Data Sensing ((N+1)th)), an operation voltage applied to the selected word line SEL WL may be changed from an initial voltage Vᵢₙₜ to a first read voltage V_{read1}, and an operation voltage applied to the unselected word line UNSEL WL may be changed from the initial voltage Vᵢₙₜ to a pass voltage Vₚₐₛₛ. In an embodiment, the operation voltage applied to the selected word line SEL WL may be precharged from the initial voltage Vᵢₙₜ to the pass voltage Vₚₐₛₛ together with the operation voltage applied to the unselected word line UNSEL WL during the voltage setting operation Bias Setting and then may be changed to the first read voltage V_{read1}.

During the operation that senses the data corresponding to the (N+1)-th address ADDR (N+1)th (Read Data Sensing ((N+1)th)), the operation voltage applied to the selected word line SEL WL may be maintained as the first read voltage V_{read1}, and the operation voltage applied to the unselected word line UNSEL WL may be maintained as the pass voltage Vₚₐₛₛ. In FIG. 9, each of the first read voltage V_{read1} and the pass voltage Vₚₐₛₛ may be a voltage of a single level but is not limited thereto, and each of the first read voltage V_{read1} and the pass voltage Vₚₐₛₛ may be configured of a plurality of read voltages and pass voltages of different levels.

After the sensing of the data corresponding to the (N+1)-th address ADDR (N+1) th is completed, the equalizing operation may be performed. Accordingly, an equalizing voltage V_{eq} of the same level may be applied to the selected word line SEL WL and the unselected word line UNSEL WL. In an embodiment, the equalizing voltage V_{eq} may be equal to or greater than the first read voltage V_{read1} and equal to or less than the pass voltage Vₚₐₛₛ, but the embodiment is not limited thereto.

When the equalizing operation is completed, the discharge operation may be performed, and thus, the voltage applied to the selected word line SEL WL and the non-selected word line UNSEL WL synchronized with V_{eq} may be discharged. In other words, a discharge voltage V_{disc} may be applied to the selected word line SEL WL and the unselected word line UNSEL WL. In FIG. 9, the discharge voltage V_{disc} may be the same as the initial voltage Vᵢₙₜ, but a voltage equal to or less than the equalizing voltage V_{eq} or the first read voltage V_{read1} is not limited and may be used as the discharge voltage V_{disc}.

Thereafter, the voltage setting operation Bias Setting may be performed again, and thus, the operation voltage applied to the selected word line SEL WL may be changed from the discharge voltage V_{disc} to a second read voltage V_{read2} for sensing the data corresponding to the (N+2)-th address ADDR (N+2)th, and the operation voltage applied to the unselected word line UNSEL WL may be changed from the discharge voltage V_{disc} to the pass voltage Vₚₐₛₛ. In an embodiment, the operation voltage applied to the selected word line SEL WL may be precharged from the discharge voltage V_{disc} to the pass voltage Vₚₐₛₛ together with the operation voltage applied to the unselected word line UNSEL WL during the voltage setting operation Bias Setting and then may be changed to the second read voltage V_{read2}.

After the voltage setting operation Bias Setting is completed, an operation that senses the data corresponding to the (N+2)-th address ADDR (N+2)th (Read Data Sensing ((N+2)th)) may be performed. At this time, the operation voltage applied to the selected word line SEL WL may be maintained as the second read voltage V_{read2}, and the operation voltage applied to the unselected word line UNSEL WL may be maintained as the pass voltage Vₚₐₛₛ. In FIG. 9, the second read voltage V_{read2} for sensing the data corresponding to the (N+2)-th address ADDR (N+2)th may be different from the first read voltage V_{read1} for sensing the data corresponding to the (N+1)-th address ADDR (N+1)th, but the second read voltage V_{read2} may be the same as the first read voltage V_{read1} in another embodiment.

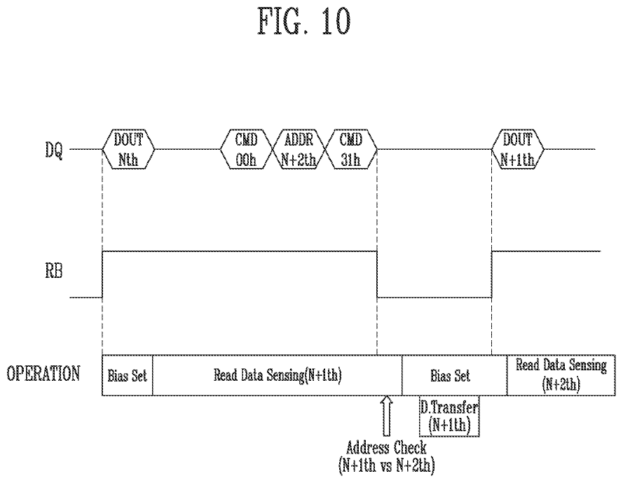

FIG. 10 is a timing diagram illustrating a cache read operation of a memory device according to an embodiment of the present disclosure.

Referring to FIGS. 1, 8, and 10, FIG. 10 shows an operation that outputs the data (DOUT Nth) corresponding to the N-th address ADDR Nth of FIG. 8 through the input/output lines DQ.

The memory device 100 may output the data (DOUT Nth) corresponding to the N-th address ADDR Nth stored in the cache register CRT through the input/output lines DQ and may sense the data corresponding to the (N+1)-th address ADDR (N+1)th (Read Data Sensing ((N+1)th)) simultaneously. In the cache read operation, since the data is stored in the data register DRT and the data stored in the cache register CRT is output simultaneously, the data corresponding to the (N+1)-th address ADDR (N+1)th may be stored in the data register DRT and the data corresponding to the N-th address ADDR Nth stored in the cache register CRT may be output to the external memory controller simultaneously.

At this time, the voltage setting operation Bias Setting may be performed before the data sensing operation (Read Data Sensing ((N+1)th)) for the selected word line. Here, the selected word line may be a word line corresponding to the (N+1)-th address ADDR (N+1)th.

The voltage setting operation Bias Setting may be an operation that changes the voltage applied to the selected word line to the read voltage for sensing the data corresponding to the (N+1)-th address ADDR (N+1)th. In an embodiment, during the voltage setting operation Bias Setting, the voltage applied to the selected word line may be changed from the discharged voltage to the read voltage. In another embodiment, during the voltage setting operation Bias Setting, the voltage applied to the selected word line may be precharged from the discharged voltage to the precharge voltage and then may be changed to the read voltage.

In an embodiment, when the data corresponding to the N-th address ADDR Nth is output, the memory device 100 may receive a subsequent cache read command and address from the memory controller through the input/output lines DQ. For example, after outputting the data corresponding to the N-th address ADDR Nth, the memory device 100 may receive the 00h command CMD 00h, the (N+2)-th address ADDR (N+2)th, and the 31h command CMD 31h through the input/output lines DQ.

At this time, when the voltage control circuit 131 receives the (N+2)-th address ADDR (N+2)th, the voltage control circuit 131 may compare the (N+1)-th address ADDR (N+1)th with the (N+2)-th address ADDR (N+2)th. At this time, a time point at which the (N+2)-th address ADDR (N+2)th is received or a time point at which reception of the 31h command CMD 31h corresponding to the (N+2)-th address ADDR (N+2)th is completed is before a time point at which the equalizing operation is performed, the voltage setting operation Bias Setting may be performed directly on the word lines of the memory device 100 without the equalizing operation and the discharge operation.

When all data corresponding to the (N+1)-th address ADDR (N+1)th is stored in the data register DRT, the data stored in the data register DRT may be transferred to the cache register CRT (D.Transfer((N+1)th)). At this time, the voltage setting operation Bias Setting may be simultaneously performed directly on the word line corresponding to the (N+2)-th address ADDR (N+2)th, which is the selected word line, without the equalizing operation and the discharge operation as described above. That is, at least a portion of the operation that transfers the data stored in the data register DRT to the cache register CRT and the voltage setting operation may be simultaneously performed.

Thereafter, the memory device 100 may output the data (DOUT (N+1)th) corresponding to the (N+1)-th address ADDR (N+1)th stored in the cache register CRT through the input/output lines DQ and may sense the data corresponding to the (N+2)-th address ADDR (N+2)th (Read Data Sensing ((N+2)th)) simultaneously. In the cache read operation, since the data is stored in the data register DRT and the data stored in the cache register CRT is output simultaneously, the data corresponding to the (N+2)-th address ADDR (N+2)th may be stored in the data register DRT and the data corresponding to the (N+1)-th address ADDR (N+1)th stored in the cache register CRT may be output to the external memory controller simultaneously.

At this time, the data sensing operation (Read Data Sensing ((N+2)th)) for the selected word line may be performed after the voltage setting operation Bias Setting. In the cache read operation of the memory device according to an embodiment of the present disclosure, the voltage setting operation Bias Setting may be performed earlier by omitting the equalizing operation and the discharge operation, and thus, the required time of the cache read operation may be shortened.

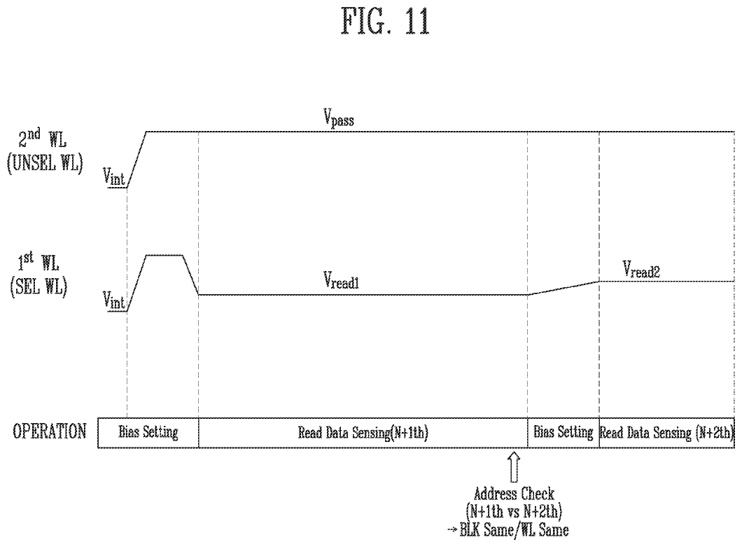

FIG. 11 is a diagram illustrating an example of a voltage applied to each of lines during a cache read operation of a memory device according to an embodiment of the present disclosure.

Referring to FIGS. 10 and 11, according to the voltage setting operation Bias Setting performed before an operation that senses the data corresponding to the (N+1)-th address ADDR (N+1)th (Read Data Sensing ((N+1)th)), an operation voltage applied to a first word line 1^{st} WL, which is the selected word line SEL WL, may be changed from the initial voltage Vᵢₙₜ to the first read voltage V_{read1}, and an operation voltage applied to a second word line 2^{nd} WL, which is the unselected word line UNSEL WL, may be changed from the initial voltage Vᵢₙₜ to the pass voltage Vₚₐₛₛ. In an embodiment, the operation voltage applied to the first word line 1^{st} WL may be precharged from the initial voltage Vᵢₙₜ to the pass voltage Vₚₐₛₛ together with the operation voltage applied to the second word line 2^{nd} WL during the voltage setting operation Bias Setting and then may be changed to the first read voltage V_{read1}.

During the operation that senses the data corresponding to the (N+1)-th address ADDR (N+1)th (Read Data Sensing ((N+1)th)), the operation voltage applied to the first word line 1^{st} WL may be maintained as the first read voltage V_{read1}, and the operation voltage applied to the second word line 2^{nd} WL may be maintained as the pass voltage Vₚₐₛₛ. In FIG. 11, each of the first read voltage V_{read1} and the pass voltage Vₚₐₛₛ may be a voltage of a single level but is not limited thereto, and each of the first read voltage V_{read1} and the pass voltage Vₚₐₛₛ may be configured of a plurality of read voltages and pass voltages of different levels.

During the operation that senses the data corresponding to the (N+1)-th address ADDR (N+1)th (Read Data Sensing ((N+1)th)), the memory device may receive the (N+2)-th address ADDR (N+2)th. A time point at which the (N+2)-th address ADDR (N+2)th is received may be before performing the equalizing operation and the discharge operation.

The memory device may compare the (N+1)-th address ADDR (N+1)th with the (N+2)-th address ADDR (N+2)th, and as a result of the comparison, a result that block addresses and word line addresses of the (N+1)-th address ADDR (N+1)th and the (N+2)-th address ADDR (N+2)th are the same may be obtained.

Accordingly, the first word line 1^{st} WL may be continuously maintained as the selected word line SEL WL, and the second word line 2^{nd} WL may be continuously maintained as the unselected word line UNSEL WL.

After the sensing of the data corresponding to the (N+1)-th address ADDR (N+1)th is completed, the voltage setting operation Bias Setting may be performed directly without performing the equalizing operation and the discharge operation. As described above, since the first word line 1^{st} WL is continuously maintained as the selected word line SEL WL, the operation voltage of the first word line 1^{st} WL may be changed from the first read voltage V_{read1} to the second read voltage V_{read2} during the voltage setting operation Bias Setting. In FIG. 11, the second read voltage V_{read2} for sensing the data corresponding to the (N+2)-th address ADDR (N+2)th may be different from the first read voltage V_{read1} for sensing the data corresponding to the (N+1)-th address ADDR (N+1)th, but the second read voltage V_{read2} may be the same as the first read voltage V_{read1} in another embodiment.

In addition, since the second word line 2^{nd} WL is continuously maintained as the unselected word line UNSEL WL, the operation voltage of the second word line 2^{nd} WL may be maintained as the pass voltage Vₚₐₛₛ during the voltage setting operation Bias Setting.

That is, the memory device according to an embodiment of the present disclosure may check in advance that the selected word line SEL WL is not changed by comparing a previously received address with a currently received address, and thus, the equalizing operation, the discharge operation, and the like may be omitted, thereby shortening the required time of the cache read operation.

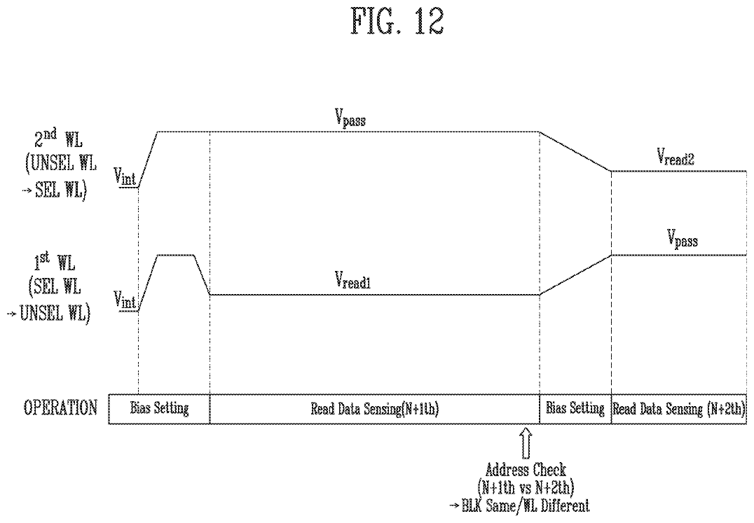

FIG. 12 is a diagram illustrating another example of a voltage applied to each of lines during a cache read operation of a memory device according to an embodiment of the present disclosure.

Referring to FIGS. 10 and 12, according to the voltage setting operation Bias Setting performed before an operation that senses the data corresponding to the (N+1)-th address ADDR (N+1)th (Read Data Sensing ((N+1)th)), an operation voltage applied to a first word line 1^{st} WL, which is the selected word line SEL WL, may be changed from the initial voltage Vᵢₙₜ to the first read voltage V_{read1}, and an operation voltage applied to a second word line 2^{nd} WL, which is the unselected word line UNSEL WL, may be changed from the initial voltage Vᵢₙₜ to the pass voltage Vₚₐₛₛ. In an embodiment, the operation voltage applied to the first word line 1^{st} WL may be precharged from the initial voltage Vᵢₙₜ to the pass voltage Vₚₐₛₛ together with the operation voltage applied to the second word line 2^{nd} WL during the voltage setting operation Bias Setting and then may be changed to the first read voltage V_{read1}.

During the operation that senses the data corresponding to the (N+1)-th address ADDR (N+1)th (Read Data Sensing ((N+1)th)), the operation voltage applied to the first word line 1st WL may be maintained as the first read voltage V_{read1}, and the operation voltage applied to the second word line 2nd WL may be maintained as the pass voltage Vₚₐₛₛ. In FIG. 12, each of the first read voltage V_{read1} and the pass voltage Vₚₐₛₛ is a voltage of a single level but is not limited thereto, and each of the first read voltage V_{read1} and the pass voltage Vₚₐₛₛ may be configured of a plurality of read voltages and pass voltages of different levels.

During the operation that senses the data corresponding to the (N+1)-th address ADDR (N+1)th (Read Data Sensing ((N+1)th)), the memory device may receive the (N+2)-th address ADDR (N+2)th. A time point at which the (N+2)-th address ADDR (N+2)th is received may be before performing the equalizing operation and the discharge operation.

The memory device may compare the (N+1)-th address ADDR (N+1)th with the (N+2)-th address ADDR (N+2)th, and as a result of the comparison, a result that block addresses of the (N+1)-th address ADDR (N+1)th and the (N+2)-th address ADDR (N+2)th are the same and word line addresses of the (N+1)-th address ADDR (N+1)th and the (N+2)-th address ADDR (N+2)th are different from each other may be obtained. Accordingly, the first word line 1^{st} WL, which is the selected word line SEL WL, according to the (N+1)-th address may be changed to the unselected word line UNSEL WL according to the (N+2)-th address, and the second word line 2nd WL, which is the unselected word line UNSEL WL, according to the (N+1)-th address may be changed to the selected word line SEL WL according to the (N+2)-th address.

After the sensing of the data corresponding to the (N+1)-th address ADDR (N+1)th is completed, the voltage setting operation Bias Setting may be performed directly without performing the equalizing operation and the discharge operation. As described above, since the first word line 1^{st} WL is changed to the unselected word line UNSEL WL according to the (N+2)-th address, the operation voltage of the first word line 1^{st} WL may be changed from the first read voltage V_{read1} to the pass voltage Vₚₐₛₛ during the voltage setting operation Bias Setting.

In addition, since the second word line 2^{nd} WL is changed to the selected word line SEL WL according to the (N+2)-th address, the operation voltage of the second word line 2^{nd} WL may be changed from the pass voltage Vₚₐₛₛ to the second read voltage V_{read2} during the voltage setting operation Bias Setting.

In FIG. 12, the second read voltage V_{read2} for sensing the data corresponding to the (N+2)-th address ADDR (N+2)th may be different from the first read voltage V_{read1} for sensing the data corresponding to the (N+1)-th address ADDR (N+1)th, but the second read voltage V_{read2} may be the same as the first read voltage V_{read1} in another embodiment.

When, as a result of comparing the (N+1)-th address ADDR (N+1)th with the (N+2)-th address ADDR (N+2)th, a result of the block addresses being different is obtained, since the read voltage and the pass voltage are only applied to word lines of a memory block different from the memory block including the first word line 1^{st} WL, the equalizing operation and the discharge operation may be performed on the memory block including the first word line, and thus, the voltage applied to the first word line 1^{st} WL may be changed to the discharge voltage (or the initial voltage) through the equalizing voltage.

That is, the memory device according to an embodiment of the present disclosure may check in advance that the selected word line SEL WL is changed by comparing a previously received address with a currently received address, and thus, the equalizing operation, the discharge operation, and the like may be omitted, thereby shortening a required time of the cache read operation.

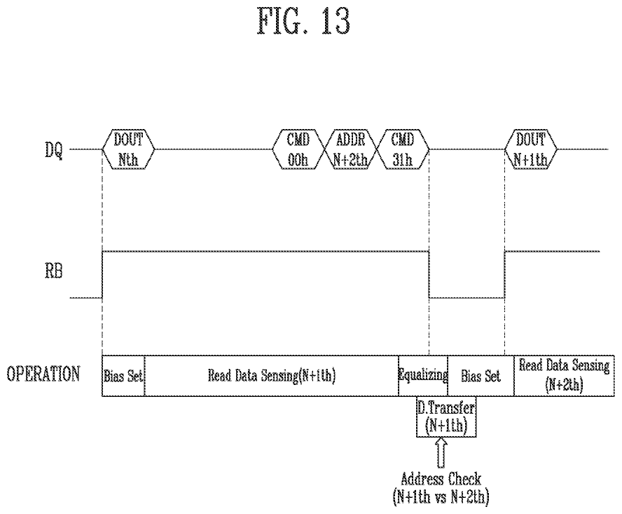

FIG. 13 is a timing diagram illustrating a cache read operation of a memory device according to another embodiment of the present disclosure.

Referring to FIGS. 1, 8, and 13, FIG. 13 shows an operation that outputs the data (DOUT Nth) corresponding to the N-th address ADDR Nth of FIG. 8 through the input/output lines DQ.

The memory device 100 may output the data (DOUT Nth) corresponding to the N-th address ADDR Nth stored in the cache register CRT through the input/output lines DQ and sense the data corresponding to the (N+1)-th address ADDR (N+1)th (Read Data Sensing ((N+1)th)) simultaneously. In the cache read operation, since the data is stored in the data register DRT and the data stored in the cache register CRT is output simultaneously, the data corresponding to the (N+1)-th address ADDR (N+1)th may be stored in the data register DRT and the data corresponding to the N-th address ADDR Nth stored in the cache register CRT may be output to the external memory controller simultaneously.

At this time, the voltage setting operation Bias Setting may be performed before the data sensing operation (Read Data Sensing ((N+1)th)) for the selected word line. Here, the selected word line may be a word line corresponding to the (N+1)-th address ADDR (N+1)th.

The voltage setting operation Bias Setting may be an operation that changes the voltage applied to the selected word line to the read voltage for sensing the data corresponding to the (N+1)-th address ADDR (N+1)th. In an embodiment, during the voltage setting operation Bias Setting, the voltage applied to the selected word line may be changed from the discharged voltage to the read voltage. In another embodiment, during the voltage setting operation Bias Setting, the voltage applied to the selected word line may be precharged from the discharged voltage to the precharge voltage and then may be changed to the read voltage.

In an embodiment, when the data corresponding to the N-th address ADDR Nth is output, the memory device 100 may receive a subsequent cache read command and address from the memory controller through the input/output lines DQ. For example, after outputting the data corresponding to the N-th address ADDR Nth, the memory device 100 may receive the 00h command CMD 00h, the (N+2)-th address ADDR (N+2)th, and the 31h command CMD 31h through the input/output lines DQ.

At this time, when the voltage control circuit 131 receives the (N+2)-th address ADDR (N+2)th, the voltage control circuit 131 may compare the (N+1)-th address ADDR (N+1)th with the (N+2)-th address ADDR (N+2)th. At this time, a time point at which the (N+2)-th address ADDR (N+2)th is received or a time point at which reception of the 31h command CMD 31h corresponding to the (N+2)-th address ADDR (N+2)th is completed is during a time point at which the equalizing operation is performed, the voltage setting operation Bias Setting may be performed directly on the word lines of the memory device 100 without the discharge operation after completing the equalizing operation.

When all data corresponding to the (N+1)-th address ADDR (N+1)th is stored in the data register DRT, the data stored in the data register DRT may be transferred to the cache register CRT (D.Transfer((N+1)th)). At this time, the voltage setting operation Bias Setting may be simultaneously performed directly on the word line corresponding to the (N+2)-th address ADDR N+2th, which is the selected word line, without the discharge operation as described above. That is, at least a portion of the operation that transfers the data stored in the data register DRT to the cache register CRT, the equalizing operation, and the voltage setting operation may be simultaneously performed.

Thereafter, the memory device 100 may output the data (DOUT (N+1)th) corresponding to the (N+1)-th address ADDR (N+1)th stored in the cache register CRT through the input/output lines DQ and may sense the data corresponding to the (N+2)-th address ADDR N+2th (Read Data Sensing (N+2th)) simultaneously. In the cache read operation, since the data is stored in the data register DRT and the data stored in the cache register CRT is output simultaneously, the data corresponding to the (N+2)-th address ADDR N+2th may be stored in the data register DRT and the data corresponding to the (N+1)-th address ADDR (N+1)th stored in the cache register CRT may be output to the external memory controller simultaneously.

At this time, the data sensing operation (Read Data Sensing (N+2th)) for the selected word line may be performed after the voltage setting operation Bias Setting. In the cache read operation of the memory device according to an embodiment of the present disclosure, the voltage setting operation Bias Setting may be performed earlier by omitting the discharge operation, and thus, the required time of the cache read operation may be shortened.

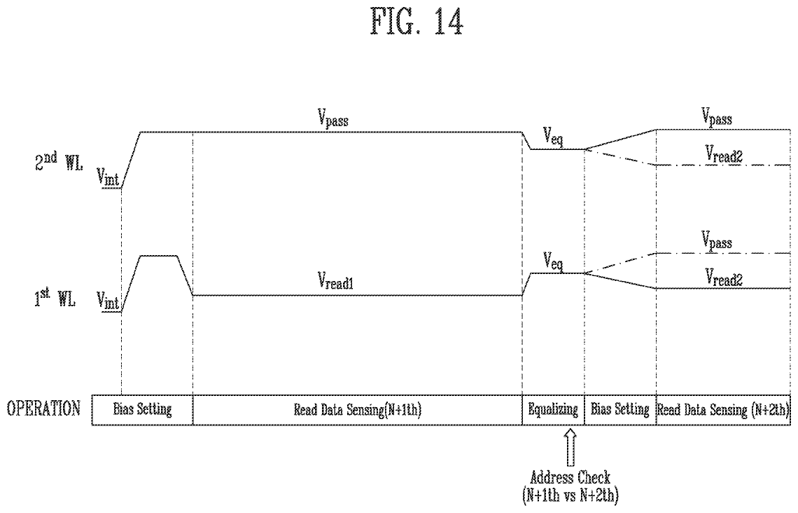

FIG. 14 is a diagram illustrating a voltage applied to each of lines during a cache read operation of a memory device according to another embodiment of the present disclosure.

Referring to FIGS. 13 and 14, according to the voltage setting operation Bias Setting performed before an operation that senses the data corresponding to the (N+1)-th address ADDR (N+1)th (Read Data Sensing ((N+1)th)), the operation voltage applied to the first word line 1^{st} WL, which is the selected word line SEL WL, may be changed from the initial voltage Vᵢₙₜ to the first read voltage V_{read1}, and the operation voltage applied to the second word line 2^{nd} WL, which is the unselected word line UNSEL WL, may be changed from the initial voltage Vᵢₙₜ to the pass voltage Vₚₐₛₛ. In an embodiment, the operation voltage applied to the first word line 1^{st} WL may be precharged from the initial voltage Vᵢₙₜ to the pass voltage Vₚₐₛₛ together with the operation voltage applied to the second word line 2^{nd} WL during the voltage setting operation Bias Setting and then may be changed to the first read voltage V_{read1}.

During the operation that senses the data corresponding to the (N+1)-th address ADDR (N+1)th (Read Data Sensing ((N+1)th)), the operation voltage applied to the first word line 1^{st} WL may be maintained as the first read voltage V_{read1}, and the operation voltage applied to the second word line 2^{nd} WL may be maintained as the pass voltage Vₚₐₛₛ. In FIG. 14, each of the first read voltage V_{read1} and the pass voltage Vₚₐₛₛ may be a voltage of a single level but is not limited thereto, and each of the first read voltage V_{read1} and the pass voltage Vₚₐₛₛ may be configured of a plurality of read voltages and pass voltages of different levels.

Thereafter, the equalizing operation may be performed on the first word line 1^{st} WL and the second word line 2^{nd} WL. Accordingly, the equalizing voltage V_{eq} may be applied to both of the first word line 1^{st} WL and the second word line 2^{nd} WL, and as a result, voltages of the first word line 1^{st} WL and the second word line 2^{nd} WL may be synchronized

During the equalizing operation, the memory device may receive the (N+2)-th address ADDR N+2th. A time point at which the (N+2)-th address ADDR N+2th is received may be after the equalizing operation is started and may be before the discharge operation is performed.

The memory device may compare the (N+1)-th address ADDR (N+1)th with the (N+2)-th address ADDR N+2th.

As a result of the comparison, a result that all of the block addresses and word line addresses of the (N+1)-th address ADDR (N+1)th and the (N+2)-th address ADDR N+2th are the same may be obtained. In this case, as indicated by a solid line, the operation voltage of the first word line 1^{st} WL may be changed from the equalizing voltage V_{eq} to the second read voltage V_{read2} during the voltage setting operation Bias Setting. In addition, the operation voltage of the second word line 2^{nd} WL may be changed from the equalizing voltage V_{eq} to the pass voltage Vₚₐₛₛ during the voltage setting operation Bias Setting.

As a result of the comparison, a result that the block addresses of the (N+1)-th address ADDR (N+1)th and the (N+2)-th address ADDR N+2th are the same and the word line addresses of the (N+1)-th address ADDR (N+1)th and the (N+2)-th address ADDR N+2th are different. In this case, as indicated by a dashed-dotted line, the operation voltage of the first word line 1^{st} WL may be changed from the equalizing voltage V_{eq} to the pass voltage Vₚₐₛₛ during the voltage setting operation Bias Setting. In addition, the operation voltage of the second word line 2^{nd} WL may be changed from the equalizing voltage V_{eq} to the second read voltage V_{read2} during the voltage setting operation Bias Setting.

In FIG. 14, the second read voltage V_{read2} for sensing the data corresponding to the (N+2)-th address ADDR N+2th may be different from the first read voltage V_{read1} for sensing the data corresponding to the (N+1)-th address ADDR (N+1)th, but the second read voltage V_{read2} may be the same as the first read voltage V_{read1} in another embodiment.

When, as a result of comparing the (N+1)-th address ADDR (N+1)th with the (N+2)-th address ADDR N+2th, a result that the block addresses are different is obtained, since the read voltage and the pass voltage are only applied to word lines of a memory block different from the memory block including the first word line 1^{st} WL, the discharge operation may be performed on the memory block including the first word line, and thus, the voltage applied to the first word line 1^{st} WL may be changed to the discharge voltage (or the initial voltage).

That is, the memory device according to an embodiment of the present disclosure may omit the discharge operation and the like by comparing a previously received address with a currently received address, thereby shortening a required time of the cache read operation.

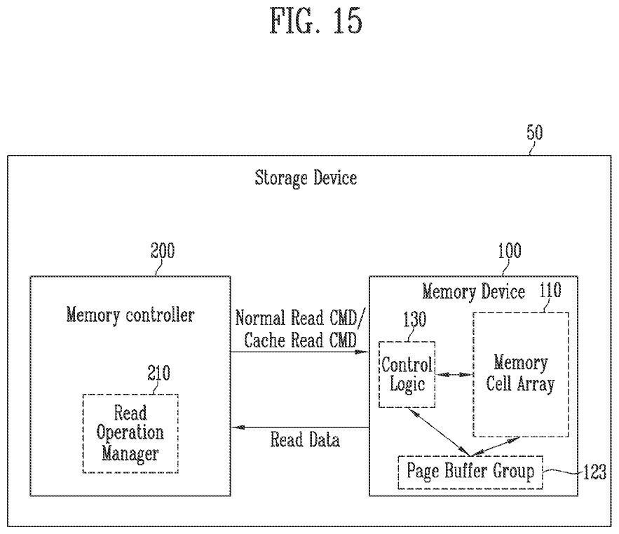

FIG. 15 is a block diagram illustrating a storage device including a memory device according to an embodiment of the present disclosure.

Referring to FIG. 15, the storage device 50 may include a memory device 100 and a memory controller 200. The storage device 50 may be a device that stores data under the control of a host such as a cellular phone, a smartphone, an MP3 player, a laptop computer, a desktop computer, a game player, a TV, a tablet PC, or an in-vehicle infotainment system. Alternatively, the storage device 50 may be a device that stores data under the control of the host that stores high-capacity data in one place, such as a server or a data center.

The storage device 50 may be manufactured as one of various types of storage devices according to a host interface that is a communication method with the host. In addition, the storage device 50 may be manufactured as any one of various types of packages.

The memory device 100 may store data. The memory device 100 operates under the control of the memory controller 200. The memory device 100 may be the memory device 100, shown in FIG. 1. Therefore, the memory device 100 may include the memory cell array 110 including the plurality of memory cells, the page buffer group 123 connected to the memory cells through the bit lines, and the control logic 130 that controls the peripheral circuit. Each of the memory cells may be configured as an SLC that stores one data bit, an MLC that stores two data bits, a TLC that stores three data bits, or a QLC capable of storing four data bits. The memory cell array may include a plurality of memory blocks. Each memory block may include a plurality of pages. In an embodiment, the page may be a unit for storing data in the memory device 100 or reading data stored in the memory device 100. The memory block may be a unit for erasing data.

In an embodiment, the memory device 100 may be various types of volatile memories, non-volatile memories, or the like. In the present specification, for convenience of description, it is assumed that the memory device 100 is a NAND flash memory.

The memory device 100 may be configured to receive a command and an address from the memory controller 200 and access an area selected by the address in the memory cell array. The memory device 100 may perform an operation instructed by the command on the area selected by the address. For example, the memory device 100 may perform a write operation (program operation), a read operation, and an erase operation. During the program operation, the memory device 100 may program data in the area selected by the address. During the read operation, the memory device 100 may read data from the area selected by the address. During the erase operation, the memory device 100 may erase data stored in the area selected by the address. In an embodiment, training information may be stored in the memory device 100.

The memory controller 200 may control an overall operation of the storage device 50.

When power is applied to the storage device 50, the memory controller 200 may execute firmware, such as a flash translation layer (FTL) for controlling communication between the host and the memory device 100.

In an embodiment, the memory controller 200 may receive data and a logical address (LA) from the host and may convert the LA into a physical address (PA) indicating an address of memory cells in the memory device 100 in which data is to be stored or from which data is to be read.

The memory controller 200 may control the memory device 100 to perform the program operation, the read operation, or the erase operation according to a request of the host. During the program operation, the memory controller 200 may provide a program command, the PA, and data to the memory device 100. During the read operation, the memory controller 200 may provide a read command and the PA to the memory device 100. During the erase operation, the memory controller 200 may provide an erase command and the PA to the memory device 100.

In an embodiment, the memory controller 200 may generate a command, an address, and data independently regardless of the request from the host and transmit the command, the address, and the data to the memory device 100. For example, the memory controller 200 may provide the command, the address, and the data for performing a program operation, a read operation, and an erase operation accompanying in performing wear leveling, read reclaim, garbage collection, and the like, to the memory device 100.

In an embodiment, the memory controller 200 may control at least two or more memory devices 100. In this case, the memory controller 200 may control the memory devices 100 according to an interleaving method to improve operation performance. The interleaving method may be a method of controlling operations for at least two memory devices 100 to overlap with each other.

In an embodiment, the memory controller 200 may include a read operation manager 210. The read operation manager 210 may provide a normal read command Normal Read CMD or a cache read command Cache Read CMD to the memory device 100 according to an external request or its own determination. The memory device 100 may provide the read data to the memory controller 200 in response to the normal read command Normal Read CMD or the cache read command Cache Read CMD.

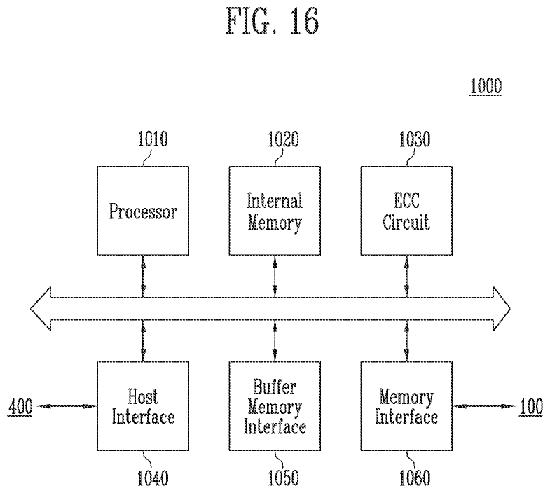

FIG. 16 is a diagram illustrating another embodiment of the memory controller of FIG. 15.

Referring to FIG. 16, the memory controller 1000 may include a processor 1010, an internal memory 1020, an error correction circuit 1030, a host interface 1040, a buffer memory interface 1050, and a memory interface 1060.

The processor 1010 may perform various operations or may generate various commands for controlling the memory device 100. When receiving a request from the host, the processor 1010 may generate a command according to the received request and may transmit the generated command to a queue controller (not shown). The processor 1010 may control a subsequent operation for the memory device 100 based on a verification result received from the memory device 100 by the memory interface 1060. In an embodiment, the processor 1010 may generate the normal read command or the cache read command.

The internal memory 1020 may store various pieces of information necessary for an operation of the memory controller 1000. For example, the internal memory 1020 may include logical and physical address map tables.

The error correction circuit 1030 may be configured to detect and correct an error of data received from the memory device 100 by using an error correction code (ECC). The processor 1010 may adjust a read voltage according to an error detection result of the error correction circuit 1030 and may control the memory device 100 to perform re-reading. In an exemplary embodiment, an error correction block may be provided as a component of the memory controller 1000.

The host interface 1040 may exchange a command, an address, data, and the like between the memory controller 1000 and the host. For example, the host interface 1040 may receive a request, an address, data, and the like from the host, and may output data read from the memory device 100 to the host. The host interface 1040 may communicate with the host using various protocols.

The buffer memory interface 1050 may transmit data between the processor 1010 and a buffer memory (not shown). The buffer memory may be used as an operation memory or a cache memory of the memory controller 1000 and may store data used in the storage device. The buffer memory may be used as a read buffer, a write buffer, a map buffer, and the like by the processor 1010.

The memory interface 1060 may exchange the command, the address, the data, and the like between the memory controller 1000 and the memory device 100. For example, the memory interface 1060 may transmit the command, the address, the data, and the like to the memory device 100 and may receive the data and the like from the memory device 100 through a channel. The memory interface 1060 may provide the cache read command or the normal read command to the memory device 100 according to an instruction of the processor 1010, and thus, the memory interface 1060 may receive the read data from the memory device 100.

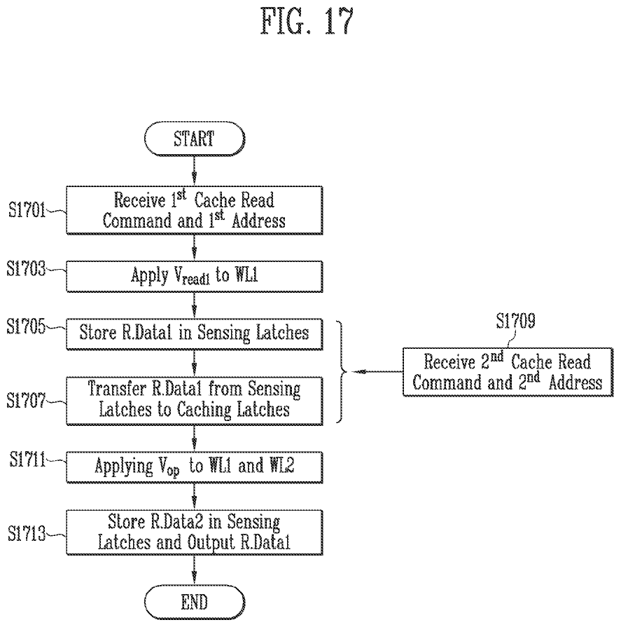

FIG. 17 is a flowchart illustrating a method of operating a memory device according to an embodiment of the present disclosure.

Referring to FIGS. 1 and 17, in operation S1701, the input/output circuit 125 of the memory device 100 may receive the first cache read command and the first address corresponding thereto. In an embodiment, the first cache read command and the first address may be provided from the external memory controller.

Next, in operation S1703, the peripheral circuit 120 of the memory device 100 may apply the first read voltage V_{read1} to the first word line WL1 according to the first address. According to the first read voltage V_{read1} applied to the first word line WL1, the memory device may sense first read data R.Data1 stored in memory cells connected to the first word line, and the sensed first read data R.Data1 may be stored in the sensing latches in the page buffer group 123 in operation S1705. The sensing latches may be connected to the memory cells through the bit lines BL1 to BLn.

Next, in operation S1707, the memory device 100 may transfer the first read data R.Data1 stored in the sensing latches from the sensing latches to the caching latches. The caching latches may be connected to the sensing latches through the bit lines BL1 to BLn.

Meanwhile, in operation S1709, the input/output circuit 125 may receive the second cache read command and the second address corresponding thereto. Operation S1709 may be performed between operations S1705 and S1707.

In operation S1711, the peripheral circuit 120 of the memory device 100 may apply the operation voltages Vₒₚ to the first word line WL1 and the second word line WL2 according to the second address. The operation voltages Vₒₚ applied to the first word line WL1 and the second word line WL2 may be determined based on a comparison result of addresses and a time point at which operation S1709 is performed. That is, the control logic 130 of the memory device 100 may determine the operation voltages Vₒₚ applied to the first word line WL1 and the second word line WL2 based on a comparison result between the first word line WL1 and the second word line WL and a time point at which the second cache read command is received. The operation voltages Vₒₚ may include one or more of the following: the pass voltage, the first read voltage corresponding to the first cache read command, the second read voltage corresponding to the second cache read command, the equalizing voltage for synchronizing the voltages of the selected word line and the unselected word line, and the discharge voltage for discharging the selected word line and the unselected word line.

For example, the first read voltage, the second read voltage, or the pass voltage may be finally applied in operation S1711, and prior to this, the equalizing voltage, the discharge voltage, and/or the like may be additionally applied selectively.

Thereafter, in operation S1713, the memory device 100 may sense second read data R.Data2 to store the second read data R.Data2 in the sensing latches and may output the first read data R.Data1 stored in the caching latch to an external device through the input/output line DQ simultaneously. The sensing operation of the second read data R.Data2 may be performed by the peripheral circuit 120 applying the second read voltage V_{read2} to the second word line WL2 according to the second address.

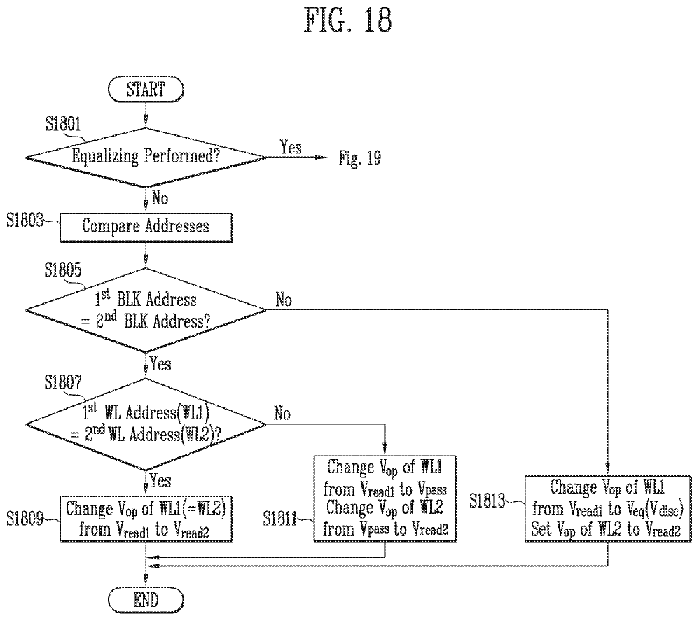

FIG. 18 is a flowchart illustrating a voltage application process in a method of operating a memory device according to an embodiment of the present disclosure.

Referring to FIGS. 1, 17, and 18, FIG. 18 may be a flowchart illustrating operation S1711 of FIG. 17 in more detail.

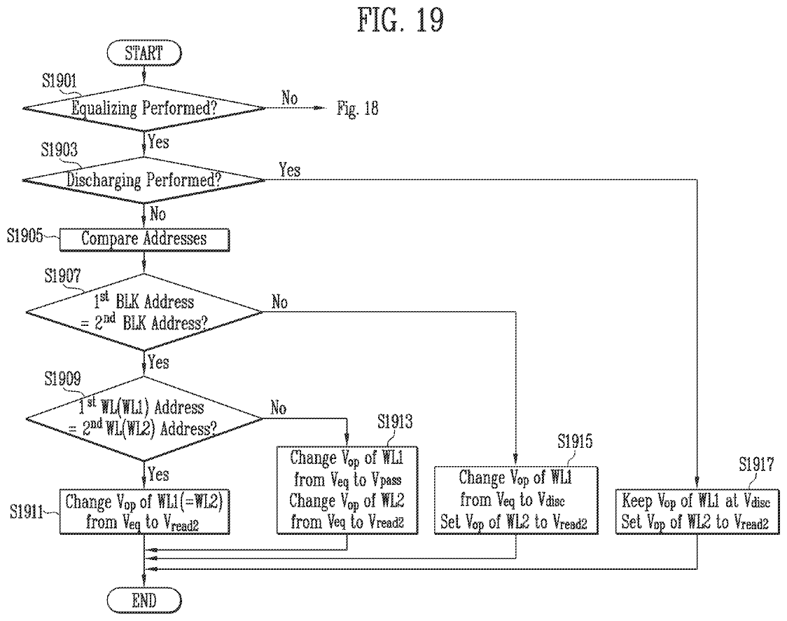

In operation S1801, the memory device 100 may check whether the equalizing operation is performed. A case in which the equalizing operation is performed is described with reference to FIG. 19 below.

When the equalizing operation is not performed, the memory device 100 may compare addresses in operation S1803. That is, the first address according to the first read command and the second address according to the second read command may be compared.

In operation S1805, the memory device 100 may check whether the block addresses of the first address and the second address are the same. When the block addresses of the first address and the second address are different, the memory device 100 may change the operation voltage Vₒₚ of the first word line WL1 from the first read voltage V_{read1} to the equalizing voltage V_{eq} according to operation S1813. In addition, the memory device 100 may set the operation voltage Vₒₚ of the second word line WL2 to the second read voltage V_{read2}. In an embodiment, the operation voltage Vₒₚ of the first word line WL1 changed to the equalizing voltage V_{eq} may be changed back to the discharge voltage V_{disc}. In another embodiment, the equalizing operation may be omitted, and in this case, the operation voltage Vₒₚ of the first word line WL1 may be changed from the first read voltage V_{read1} to the equalizing voltage V_{eq}.

When the block addresses of the first address and the second address are the same, in operation S1807, the memory device 100 may check whether the word line addresses of the first address and the second address are the same. That is, it may be checked whether the first word line WL1 and the second word line WL2 are the same. When the word line addresses of the first address and the second address are different, the memory device 100 may change the operation voltage Vₒₚ of the first word line WL1 from the first read voltage V_{read1} to the pass voltage Vₚₐₛₛ according to operation S1811. In addition, the memory device 100 may change the operation voltage Vₒₚ of the second word line WL2 from the pass voltage Vₚₐₛₛ to the second read voltage V_{read2}.

When the word line addresses of the first address and the second address are the same, since the first word line WL1 and the second word line WL2 are the same, the memory device 100 may change the operation voltage Vₒₚ of the first word line WL1 from the first read voltage V_{read1} to the second read voltage V_{read2} according to operation S1809. When the first read voltage V_{read1} and the second read voltage V_{read2} are the same, the operation voltage Vₒₚ of the first word line WL1 may be identically maintained. In addition, the operation voltages Vₒₚ of the unselected word lines may be maintained as the pass voltage Vₚₐₛₛ.

FIG. 19 is a flowchart illustrating a voltage application process in a method of operating a memory device according to another embodiment of the present disclosure.

Referring to FIGS. 1, 17, and 19, FIG. 19 may be a flowchart illustrating operation S1711 of FIG. 17 in more detail.

In operation S1901, the memory device 100 may check whether the equalizing operation is performed. This may be the same operation as operation S1801 of FIG. 18. An operation of the memory device 100 of a case in which the equalizing operation is not performed is the same as described with reference to FIG. 18.

When the equalizing operation is performed, the memory device 100 may check whether the discharge operation is performed in operation S1903. When the discharge operation is performed, the memory device 100 may maintain the operation voltage of the first word line as the discharge voltage V_{disc} according to operation S1917. In addition, the memory device 100 may set the voltage of the second word line WL2 to the second read voltage V_{read2}.

When the discharge operation is not performed, the memory device 100 may compare the addresses in operation

S1905. That is, the first address according to the first read command and the second address according to the second read command may be compared.

In operation S1907, the memory device 100 may check whether the block addresses of the first address and the second address are the same. When the block addresses of the first address and the second address are different, the memory device 100 may change the operation voltage Vₒₚ of the first word line WL1 from the equalizing voltage V_{eq} to the discharge voltage V_{disc} according to operation S1915. In addition, the memory device 100 may set the operation voltage Vₒₚ of the second word line WL2 to the second read voltage V_{read2}.

When the block addresses of the first address and the second address are the same, the memory device 100 may check whether the word line addresses of the first address and the second address are the same in operation S1909. That is, it may be checked whether the first word line WL1 and the second word line WL2 are the same. When the word line addresses of the first address and the second address are different, the memory device 100 may change the operation voltage Vₒₚ of the first word line WL1 from the equalizing voltage V_{eq} to the pass voltage Vₚₐₛₛ according to operation S1913. In addition, the memory device 100 may change the operation voltage Vₒₚ of the second word line WL2 from the equalizing voltage V_{eq} to the second read voltage V_{read2}.

When the word line addresses of the first address and the second address are the same, since the first word line WL1 and the second word line WL2 are the same, the memory device 100 may change the operation voltage Vₒₚ of the first word line WL1 from the equalizing voltage V_{eq} to the second read voltage V_{read2} according to operation S1911. In addition, the operation voltages Vₒₚ of the unselected word lines may be changed from the equalizing voltage V_{eq} to the pass voltage Vₚₐₛₛ.

What is claimed is:

1. A memory device comprising:
a memory cell array including a plurality of memory cells respectively connected to a plurality of word lines;
a peripheral circuit comprising:
a voltage generation circuit generating a voltage to be applied to the memory cell array; and
page buffers connected to the memory cells through bit lines and latching data sensed from the memory cells; and
a control logic configured to sense data stored in the memory cells in response to a cache read command received from an external device and configured to control the peripheral circuit to output data latched in the page buffers to the external device,
wherein the control logic is configured to control the peripheral circuit to generate an operation voltage to be applied to the word lines based on a comparison result of a first address corresponding to a first cache read command received from the external device and a second address corresponding to a second cache read command.

2. The memory device of claim 1, wherein the control logic is configured to control the peripheral circuit to receive word line state information indicating a voltage applied to the word lines from the peripheral circuit and configured to generate the operation voltage based on the word line state information.

3. The memory device of claim 2, wherein the operation voltage includes at least one of a pass voltage, a first read voltage corresponding to the first cache read command, a second read voltage corresponding to the second cache read command, an equalizing voltage for synchronizing a voltage of a selected word line and an unselected word line, and a discharge voltage for discharging the selected word line and the unselected word line.

4. The memory device of claim 3, wherein the control logic is configured to generate the equalizing voltage and the discharge voltage based on the word line state information corresponding to a time point at which a reception of the second cache read command is completed.

5. The memory device of claim 4, wherein, when the word line state information indicates that the equalizing voltage and the discharge voltage are not applied to a first word line corresponding to the first address, the control logic is configured to control the peripheral circuit so that an operation voltage applied to the first word line is changed from the first read voltage to the pass voltage or the second read voltage.

6. The memory device of claim 5, wherein, when a block address and a word line address of the first address and the second address are the same, the control logic is configured to control the peripheral circuit so that the operation voltage applied to the first word line is changed from the first read voltage to the second read voltage, and an operation voltage applied to the unselected word line is maintained as the pass voltage.

7. The memory device of claim 5, wherein, when block addresses of the first address and the second address are the same and word line addresses of the first address and the second address are different, the control logic is configured to control the peripheral circuit so that the operation voltage applied to the first word line is changed from the first read voltage to the pass voltage and an operation voltage applied to a second word line corresponding to the second address is changed from the pass voltage to the second read voltage.

8. The memory device of claim 5, wherein, when block addresses of the first address and the second address are different, the control logic is configured to control the peripheral circuit so that the operation voltage applied to the first word line is changed from the first read voltage to one or more operation voltages from among the equalizing voltage and the discharge voltage.

9. The memory device of claim 4, wherein, when the word line state information indicates that the equalizing voltage is applied to a first word line corresponding to the first address and the discharge voltage is not applied to the first word line, the control logic is configured to control the peripheral circuit so that an operation voltage applied to the first word line is changed from the equalizing voltage to the pass voltage or the second read voltage.

10. The memory device of claim 9, wherein, when a block address and a word line address of the first address and the second address are the same, the control logic is configured to control the peripheral circuit so that an operation voltage applied to the first word line is changed from the equalizing voltage to the second read voltage and an operation voltage applied to an unselected word line is changed from the equalizing voltage to the pass voltage.

11. The memory device of claim 9, wherein, when block addresses of the first address and the second address are the same and word line addresses of the first address and the second address are different, the control logic is configured to control the peripheral circuit so that the operation voltage applied to the first word line is changed from the equalizing voltage to the pass voltage and an operation voltage applied to a second word line corresponding to the second address is changed from the equalizing voltage to the second read voltage.

12. The memory device of claim 9, wherein, when block addresses of the first address and the second address are different, the control logic is configured to control the peripheral circuit so that the operation voltage applied to the first word line is changed from the equalizing voltage to the discharge voltage.

13. The memory device of claim 1, wherein each of the page buffers includes a sensing latch that latches read data sensed through the bit lines and a caching latch that caches data latched in the sensing latch.

14. The memory device of claim 13, wherein the control logic is configured to control the peripheral circuit so that second read data stored at a position corresponding to the second address is stored in the sensing latch and first read data corresponding to the first cache read command and stored in the caching latch is output in response to the second cache read command.

15. A method of operating a memory device, the method comprising:
applying a first read voltage to a first word line corresponding to a first address, among a plurality of memory cells connected to a plurality of word lines, in response to a first cache read command;
sensing first read data stored at a position corresponding to the first address through bit lines to store the first read data in sensing latches connected to the memory cells through the bit lines;
receiving a second cache read command and a second address;
moving the first read data stored in the sensing latches to caching latches connected to the sensing latches through the bit lines;
applying an operation voltage determined based on a comparison result of the first address and the second address to the first word line and a second word line corresponding to the second address; and
sensing second read data stored at a position corresponding to the second address to store the second read data in the sensing latches and outputting the first read data stored in the caching latch.

16. The method of claim 15, wherein an operation voltage applied to the first word line includes at least one of a pass voltage, the first read voltage, a second read voltage corresponding to the second cache read command, an equalizing voltage for synchronizing voltages of a selected word line and an unselected word line, and a discharge voltage for discharging the selected word line and the unselected word line.

17. The method of claim 16, wherein, when the equalizing voltage and the discharge voltage are not applied to the first word line at a time point at which reception of the second cache read command is completed, the operation voltage applied to the first word line is changed from the first read voltage to the pass voltage or the second read voltage.

18. The method of claim 17, wherein, when a block address and a word line address of the first address and the second address are the same, the operation voltage applied to the first word line is changed from the first read voltage to the second read voltage, and
wherein, when the block addresses of the first address and the second address are the same and the word line addresses of the first address and the second address are different, the operation voltage applied to the first word line is changed from the first read voltage to the pass voltage and an operation voltage applied to the second word line is changed from the pass voltage to the second read voltage.

19. The method of claim 16, wherein, when the equalizing voltage is applied to the first word line and the discharge voltage is not applied at a time point at which reception of the second cache read command is completed, an operation voltage applied to the first word line is changed from the equalizing voltage to the pass voltage or the second read voltage.

20. The method of claim 19, wherein, when a block address and a word line address of the first address and the second address are the same, the operation voltage applied to the first word line is changed from the equalizing voltage to the second read voltage, and
wherein, when the block addresses of the first address and the second address are the same and the word line addresses of the first address and the second address are different, the operation voltage applied to the first word line is changed from the equalizing voltage to the pass voltage and an operation voltage applied to the second word line is changed from the equalizing voltage to the second read voltage.
